(19) United States
(12) Patent Application Publication
(10) Pub. No.: US 2025/0220966 A1
(43) Pub. Date: Jul. 3, 2025

(54) REDUCTION OF METAL LOSS DURING GATE PATTERNING

(71) Applicant: Taiwan Semiconductor Manufacturing Company, Ltd., Hsinchu (TW)

(72) Inventors: Tefu Yeh, Kaohsiung (TW); Chun-Liang Chen, Hsinchu (TW); Cheng-Chieh Tu, Hsinchu (TW); Jo-Chun Hung, Hsinchu (TW); Y.L. Cheng, Tainan (TW); Ying-Liang Chuang, Hsinchu (TW)

(73) Assignee: Taiwan Semiconductor Manufacturing Company, Ltd., Hsinchu (TW)

(21) Appl. No.: 18/397,398

(22) Filed: Dec. 27, 2023

(51) Int. Cl. H01L 29/423; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 84/0167; H10D 84/0177; H10D 84/038; H10D 84/85

(57) ABSTRACT

Semiconductor structures and methods for fabricating semiconductor structures are provided. A method includes forming a first structure and a second structure over a substrate; forming a material layer over each structure; covering the first structure with a mask, wherein the second structure is uncovered; and performing an etch process to remove the material layer from the second structure, wherein the etch process is performed with an etchant comprising a first component and an oxidant, and wherein the first component is selected from an organic acid having a molecular weight of from 14 to 10⁴ g/mol and an organic base having a molecular weight of from 20 to 10⁴ g/mol.

### BACKGROUND

Semiconductor devices are used in a large number of electronic devices, such as computers, cell phones, and others. Semiconductor devices comprise integrated circuits that are formed on semiconductor wafers by depositing many types of thin films of material over the semiconductor wafers, and patterning the thin films of material to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. To achieve these goals, fin FETs (FinFETs) or multi-gate devices such as gate-all-around (GAA) FETs that use nanosheets are being used. FinFETs and multi-gate devices not only improve area density, but also improve gate control of the channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method in accordance with some embodiments.

FIGS. 2-13 are schematic cross-section views of successive stages of fabrication of the semiconductor structure according to the method of FIG. 1 in accordance with some embodiments, wherein FIGS. 2, 4, 6, 8, 10, and 12 are schematic Y-cut cross-section views, and wherein FIGS. 3, 5, 7, 9, 11, and 13 are schematic X-cut cross-section views of the same stage of fabrication of the semiconductor structure as the immediately preceding Figure.

FIG. 14 is a schematic X-cut cross-section view NFET and PFET regions during further processing in accordance with some embodiments.

FIG. 15 is an overhead layout diagram illustrating dimensions and spacing of oxide diffusion regions in accordance with some embodiments.

### DETAILED DESCRIPTION

The following disclosure provides many different embodiments, or examples, for implementing different features described herein. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In certain embodiments herein, a “material layer” is a layer that includes at least 50 wt. % of the identified material, for example at least 60 wt. % of the identified material, or at least 75 wt. % of the identified material, at least 90 wt. % of the identified material; or at least 99 wt. % of the identified material; and a layer that is a “material” includes at least 50 wt. % of the identified material, for example at least 60 wt. % of the identified material, at least 75 wt. % of the identified material, at least 90 wt. % of the identified material or at least 99 wt. % of the identified material . . . . For example, certain embodiments, each of a titanium nitride layer and a layer that is titanium nitride is a layer that is at least 50 wt. %, at least 60 wt. %, at least 75 wt. %, titanium nitride, at least 90 wt. % titanium nitride, or at least 99 wt. % titanium nitride.

Unless stated otherwise, molecular weight refers to weight average molecular weight (Mw). As used herein, “a,” “an,” or “the” means one or more unless otherwise specified. The term “or” can be conjunctive or disjunctive. Open terms such as “include,” “including,” “contain,” “containing” and the like mean “comprising.” The term “about” as used in connection with a numerical value throughout the specification and the claims denotes an interval of accuracy, familiar and acceptable to a person skilled in the art. In general, such interval of accuracy is ±ten percent. Thus, “about ten” means nine to eleven. All numbers in this description indicating amounts, ratios of materials, physical properties of materials, and/or use are to be understood as modified by the word “about,” except as otherwise explicitly indicated. As used herein, the “%” described in the present disclosure refers to the weight percentage unless otherwise indicated.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments herein provide for forming semiconductor devices, such as FinFET or multi-gate transistors. Multi-gate transistors include those transistors whose gate structures are formed on at least two-sides of a channel region. These multi-gate devices may include a p-type metal-oxide-semiconductor (PMOS) multi-gate device and/or an n-type metal-oxide-semiconductor (NMOS) multi-gate device. Specific examples may be presented and referred to herein as a gate-all-around (GAA) device. A GAA device includes any device that has its gate structure, or portion thereof, formed on 4-sides of a channel region (e.g., surrounding a portion of a channel region).

Structures presented herein also include embodiments that have channel regions in the form of nanosheets. The term “nanosheet” designates any material portion with nanoscale, or even microscale dimensions, and having an elongated shape, regardless of the cross-sectional shape of this portion. Thus, this term designates both circular and substantially circular cross-section elongated material portions, e.g., nanowires, and beam or bar-shaped material portions including for example a cylindrical or substantially rectangular cross-section.

As described herein, a method is provided to avoid loss of metal gate boundary material during processing. For example, formation of an NMOS device adjacent to a PMOS device may include formation of a material, such as a transition metal, over both devices before selectively masking and removing the material from one of the devices. A method herein avoids damage to the masked material layer, and to the structure underlying the masked material layer, by using a wet etching process with an etchant that does not penetrate deeply into the mask. For example, the etchant and etching conditions may be selected such that the etchant penetrates into the mask by a maximum dimension, such as a lateral or non-vertical dimension, of no more than 5 nm, such as no more than 4 nm, no more than 3 nm, or no more than 2 nm.

Reducing the dimension or depth of penetration of the etchant into the mask reduces the lateral dimension of mask needed to protect the masked region. Thus, adjacent transistors may be located closer to one another. In other words, transistor density may be increased over the semiconductor structure.

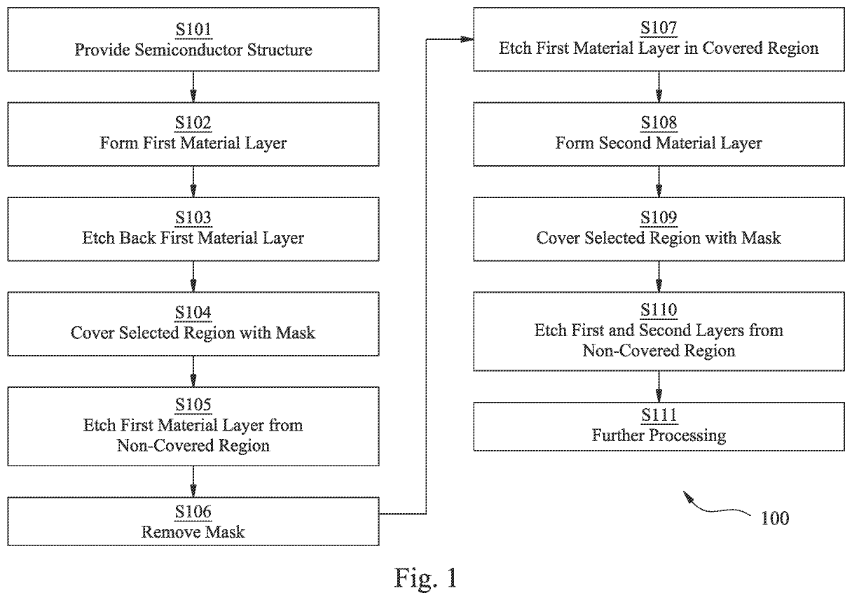

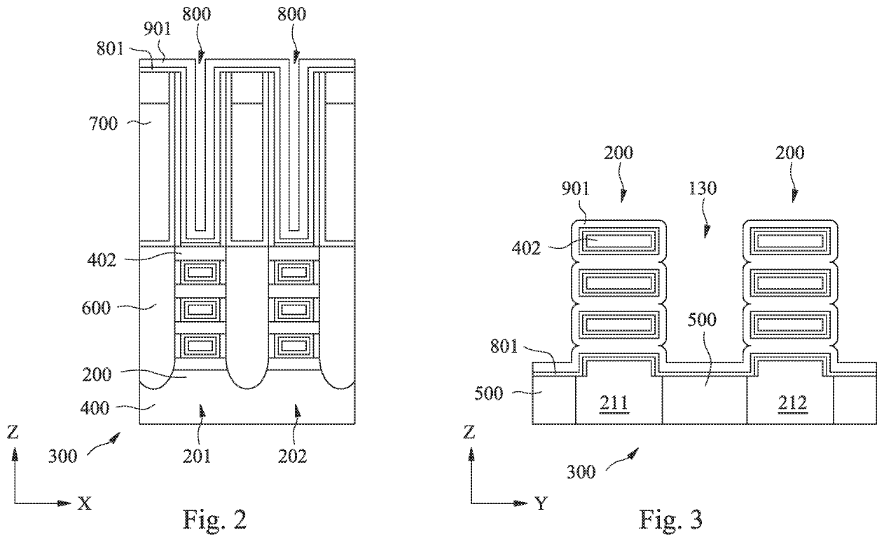

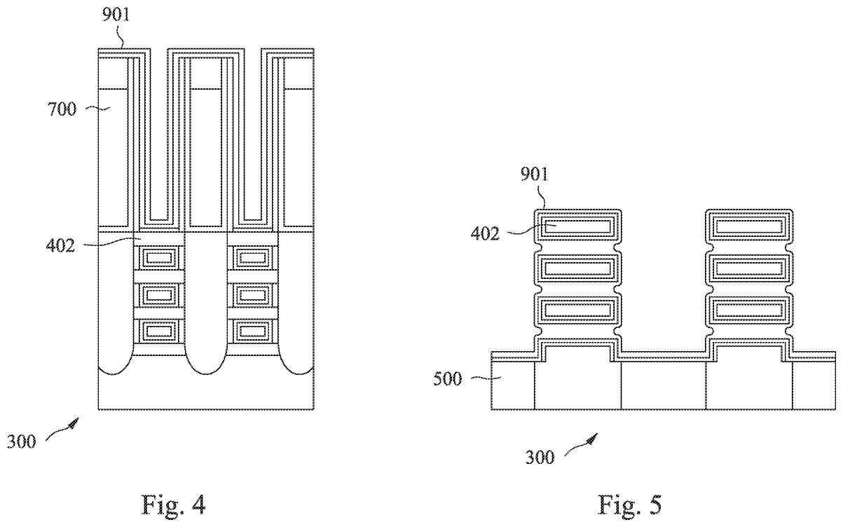

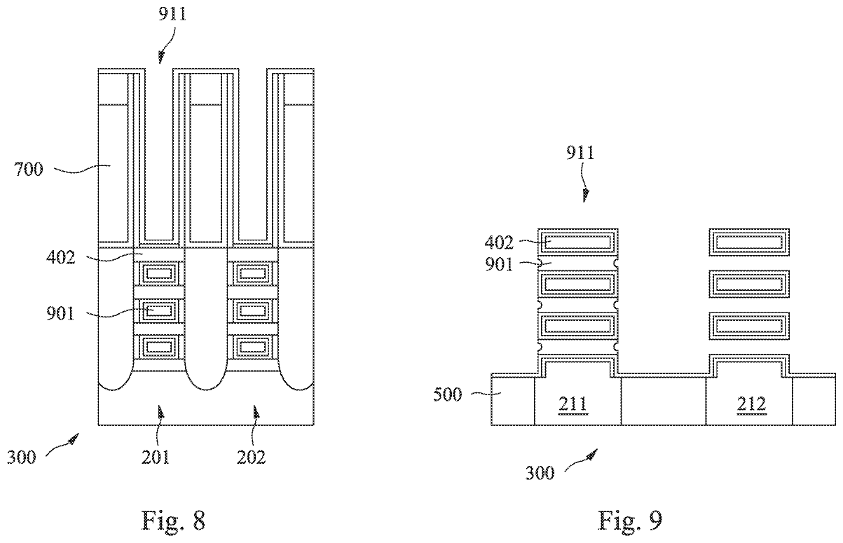

Referring to FIG. 1, a method 100 for fabricating a semiconductor structure is described. The method 100 of FIG. 1 is described in conjunction with FIGS. 2-3, 4-5, 6-7, 8-9, 10-11, and 12-13, each pair of which illustrate a semiconductor structure 200 at a same stage of fabrication. FIGS. 2, 4, 6, 8, 10, and 12 are schematic Y-cut cross-section views, and FIGS. 3, 5, 7, 9, 11, and 13 are schematic X-cut cross-section views.

Cross-referencing FIGS. 1 and 2-3, method 100 includes providing a semiconductor structure 300 over a semiconductor substrate 400 for further processing at operation S101. In some embodiments, the substrate 400 may be a semiconductor substrate such as a silicon (Si) substrate. The substrate 400 may include various layers, including conductive or insulating layers formed on a semiconductor substrate. The substrate 400 may include various doping configurations depending on design requirements as is known in the art. For example, different doping profiles (e.g., p-well, n-well) may be formed on the substrate 400 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 400 includes a single crystalline semiconductor layer on at least its surface portion. The substrate 400 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 400 may include a compound semiconductor and/or an alloy semiconductor. In the illustrated embodiment, the substrate 400 is made of crystalline Si.

One or more epitaxial layers are formed over the substrate 400. In some embodiments, an epitaxial stack is formed over the substrate 400 and includes first epitaxial layers (not shown) of a first composition interposed by second epitaxial layers 402 of a second composition. The first and second composition may be different. Embodiments are possible including those that provide for a first composition and a second composition having different oxidation rates and/or etch selectivity. In an embodiment, the first epitaxial layers are SiGe and the second epitaxial layers 402 are silicon. In embodiments wherein the first epitaxial layer includes SiGe and the second epitaxial layer 402 includes silicon, the silicon oxidation rate is less than the SiGe oxidation rate. It is noted that three layers of second epitaxial layers 402 are illustrated in the Figures, which is for illustrative purposes only and not intended to be limiting beyond what is specifically recited in the claims. It can be appreciated that any number of epitaxial layers may be formed in the epitaxial stack; the number of layers depending on the desired number of channels regions for the device 300. In some embodiments, the number of second epitaxial layers 402 is between two and ten, such as six or seven.

In some embodiments, the first epitaxial layers have a thickness ranging from about 5 nm to about 15 nm. The first epitaxial layers may be substantially uniform in thickness. In some embodiments, the second epitaxial layers 402 have a thickness ranging from about 5 nm to about 15 nm. In some embodiments, the second epitaxial layers 402 are substantially uniform in thickness. The epitaxial layers 402 may serve as channel region(s) for a subsequently formed multi-gate device and has a thickness chosen based on device performance considerations. The first epitaxial layers may serve to define a gap between adjacent channel region(s) for a subsequently formed multi-gate device and has a thickness chosen based on device performance considerations.

By way of example, epitaxial growth of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the second epitaxial layers 402 include the same material as the substrate 400. In some embodiments, the first epitaxial layers and the second epitaxial layers 402 include a different material than the substrate 400. As stated above, in at least some examples, the first epitaxial layer includes an epitaxially grown Si₁₋ₓGeₓ layer (wherein x is from about 10 to about 55%) and the second epitaxial layer 402 includes an epitaxially grown silicon (Si) layer. Alternatively, in some embodiments, either of the first epitaxial layers and second epitaxial layers 402 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GalnP, and/or GaInAsP, or combinations thereof. As discussed, the materials of the first epitaxial layers and second epitaxial layers 402 may be chosen based on providing differing oxidation, etch selectivity properties. In various embodiments, the first epitaxial layers and second epitaxial layers 402 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack are SiGe layers (not shown). In alternative embodiments, the bottom layer of the epitaxial stack is a Si layer and the top layer of the epitaxial stack is a SiGe layer (not shown).

As shown in FIG. 3, the epitaxial stack is patterned to form semiconductor fins 200 and trenches 130. In some embodiments, a mask layer (not shown) is formed over the epitaxial stack. The mask layer may include a first mask sublayer and a second mask sublayer. A certain first mask sublayer is a pad oxide layer made of a silicon oxide, which may be formed by a thermal oxidation. A certain second mask sublayer is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer is patterned into a mask pattern by using patterning operations including photolithography and etching. Operation S806 subsequently patterns the epitaxial stack in an etching process, such as a dry etch (e.g., reactive ion etching), a wet etch, and/or other suitable process, through openings defined in the patterned mask layer. The stacked epitaxial layers 402 are thereby patterned into the fin 200. The process for forming fins 200 may result in the formation of trenches 130 between parallel fins 200, as shown in FIG. 3.

Each fin 200 protrudes upwardly in the Z-direction from the substrate 400 and extends lengthwise in the X-direction. Sidewalls of each fin 200 may be straight or inclined (not shown). The fins 200 may have a same width or different widths.

As shown in FIG. 3, shallow trench isolation (STI) features (also denoted as STI features) 500 are formed in trenches 130 adjacent to each fin 200. The STI features 500 may be formed by first filling the trenches 130 around each fin 200 with a dielectric material layer to cover top surfaces and sidewalls of the fin 200 (not shown). The dielectric material layer may include one or more dielectric materials. The dielectric material layer may include silicon oxide (SiO₂). Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer (not shown) are revealed, and the dielectric material layer is recessed to form the shallow trench isolation (STI) features (also denoted as STI features) 500, as shown in FIG. 2. In the illustrated embodiment, the STI features 500 are formed on the substrate 400. Any suitable etching technique may be used to recess the isolation features 500 including dry etching, wet etching, RIE, and/or other etching methods, and in an embodiment, an anisotropic dry etching is used to selectively remove the dielectric material of the isolation features 500 without etching the fin 200. The mask layer (not shown) may also be removed before, during, and/or after the recessing of the isolation features 500. In some embodiments, the mask layer is removed by the CMP process performed prior to the recessing of the isolation features 500. In some embodiments, the mask layer is removed by an etchant used to recess the isolation features 500.

Though not shown in the Figures, sacrificial gates are formed over the stack of second epitaxial layers 402. For example, in certain embodiments, a sacrificial material may include a sacrificial gate dielectric material and a sacrificial gate electrode material. The sacrificial gate dielectric layer be blanket deposited first. The sacrificial gate dielectric layer includes silicon oxide, silicon nitride, or a combination thereof. The thickness of the sacrificial gate dielectric layer is in a range from 1 nm to 5 nm in some embodiments. The sacrificial gate electrode layer is then blanket deposited on the sacrificial gate dielectric layer. The thickness of the sacrificial gate electrode layer is in a range from 100 nm to 200 nm in some embodiments. The sacrificial gate electrode layer includes silicon such as polycrystalline silicon or amorphous silicon. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Further, gate masks may be formed over the sacrificial material. The gate masks may include a silicon oxide mask and a silicon nitride mask. The gate masks are patterned and etched, and then the sacrificial material is etched to form the sacrificial gates.

After formation of sacrificial gates, spacers may be formed, source/drain regions 600 are defined and formed, and interlayer dielectric (ILD) structures 700 are formed over the source/drain regions 600 and between the sacrificial gates. “Source/drain region(s)” may refer to a source or a drain, individually or collectively dependent upon the context. Then, the sacrificial gate structures are removed, defining gate cavities 800 over the fin 200 and between the ILD structures 700, as shown in FIG. 2. Further, the first epitaxial layers of the epitaxial stack are removed, such that the remaining second epitaxial layers 402 form suspended nanosheets 402 as shown in FIG. 3. The nanosheets 402 constitute channel regions that extend between source/drain regions 600 and are parallel and vertically arranged along the Z direction.

As shown in FIGS. 2-3, a gate dielectric layer 801 may be deposited over the structure and around the nanosheets 402. In exemplary embodiments, the gate dielectric layer 801 is deposited conformally and each nanosheet 402 is wrapped in gate dielectric 801. In accordance with some embodiments, the gate dielectric layer 801 comprises silicon oxide, silicon nitride, or multilayers thereof. In some embodiments, the gate dielectric layer 801 is a high-k dielectric material, and in these embodiments, the gate dielectric layer 801 may have a k value greater than about 7.0, and may include a metal oxide or a silicate of Hf, Al, Zr, La, Mg, Ba, Ti, Pb, and combinations thereof. The formation methods of the gate dielectric layer 801 may include Molecular-Beam Deposition (MBD), ALD, PECVD, and the like.

Thus, operation S101, may form the semiconductor structure 300 as described above.

Cross-referencing FIGS. 1 and 2-3, method 100 further includes at operation S102 forming a first material layer 901 in the gate cavities 800 and around the nanosheets 402. For example, a first material may be blanket deposited over the ILD structures 700, in the gate cavities 800, and around the nanosheets 402 as shown in FIG. 2, and over the STI features 500, fins 200, and nanosheets 402, as shown in FIG. 3. In certain embodiments, the first material fills the space between nanosheets 402 and merges, as shown in FIGS. 2-3.

In certain embodiments, the first material layer 901 is formed with a thickness of at least 10 Å, such as at least 15 Å, at least 20 Å, at least 25 Å, at least 30 Å, or at least 32.5 Å. In certain embodiments, the first material layer 901 is formed with a thickness of no more than 50 Å, such as no more than 45 Å, no more than 40 Å, no more than 35 Å, or no more than 32.5 Å.

In certain embodiments, the fin 200 of FIG. 2 includes a NMOS FET (“NFET”) region 201 and a PMOS FET (“PFET”) region 202. Further, the fins 200 in FIG. 3 each form an NMOS FET (“NFET”) region 211 and a PMOS FET (“PFET”) region 212, respectively.

In certain embodiments, the first material layer 901 is formed from a metal, such as a transition metal. For example, the first material layer 901 may be or include titanium, tungsten, vanadium, niobium, manganese, molybdenum, aluminum, or a combination thereof. In certain embodiments, the first material layer 901 is an NFET work function adjustment layer.

In certain embodiments, the first material layer 901 is formed by chemical vapor deposition (CVD), physical vapor deposition (PVD) including sputtering, atomic layer deposition (ALD) or other suitable method.

Cross-referencing FIGS. 1 and 4-5, method 100 further includes at operation S103 etching the first material layer 901. Specifically, the portions of the first material layer 901 overlying the ILD structures 700, overlying the STI features 500, and overlying the uppermost nanosheet 402 are etched back to a desired vertical thickness. In certain embodiments, the etch process at operation S103 is anisotropic. In certain embodiments, the etch process at operation S103 is a dry etch or plasma etch.

In certain embodiments, after etching, the first material layer 901 has a thickness of at least 5 Å, such as at least 10 Å, at least 12 Å, at least 15 Å, or at least 17 Å. In certain embodiments, after etching, the first material layer 901 has a thickness of no more than 30 Å, such as no more than 25 Å, no more than 20 Å, no more than 18 Å, or no more than 17 Å.

In certain embodiments, after etching, the first material layer 901 has a thickness of at least 0.5 nm, such as at least 1 nm, at least 2 nm, at least 5 nm, at least 10 nm, at least 15 nm, or at least 20 nm. In certain embodiments, after etching, the first material layer 901 has a thickness of no more than 20 nm, such as no more than 15 nm, no more than 10 nm, no more than 5 nm, or no more than 2 nm.

Cross-referencing FIGS. 1 and 6-7, method 100 further includes at operation S104 covering a selected region of the structure with a mask 910. The mask 910 may include a coating. For example, the coating may be a bottom anti-reflective coating (BARC). The BARC may provide for absorption of radiation incident to the substrate during photolithography processes, including exposure of an overlying photoresist layer. In certain embodiments, the coating may be formed with a thickness of from 80 to 200 nanometers (nm).

The mask 910 may further include reflective multilayers (ML) over the coating. In exemplary embodiments, the reflective multilayers have a total thickness of from 3 to 7 nanometers (nm).

Covering the selected region of the structure with the mask 910 may include removing the mask 910 from a non-selected region. For example, a photosensitive mask (e.g., photoresist) may be formed over the mask 910. The photoresist may be positive-tone or negative-tone resist. In an embodiment, the photoresist is chemical amplified photoresist (CAR). The photoresist may include a polymer, a photoacid generator (PAG), which provides the solubility change to the developer, a solvent, and/or other suitable compositions. The photoresist may be formed by processes such as coating (e.g., spin-on coating) and soft baking. In exemplary embodiments, the photoresist has a thickness of from 80 to 100 nanometers (nm).

After forming the photoresist, the photoresist is patterned. For example, the method may use various and/or varying wavelengths of radiation to expose the energy-sensitive photoresist layer. In an embodiment, the mask is irradiated using ultraviolet (UV) radiation or extreme ultraviolet (EUV) radiation. The radiation beam may additionally or alternatively include other radiation beams such as ion beam, x-ray, extreme ultraviolet, deep ultraviolet, and other proper radiation energy. In an example, the photoresist includes photo-acid generator (PAG) that generates acid during the exposure process thus changing the solubility of the exposed/non-exposed material. Lithography processes include immersion lithography, photolithography, optical lithography and/or other patterning methods which may transfer a pattern onto the photosensitive layer. Patterning may further include a post-exposure bake (PEB) process. During the baking process, the photoresist layer is provided at an elevated temperature. This may allow more acid to be generated from the photo-generated acids through a chemical amplification process. Further, patterning may include developing the photoresist layer. The developing may form a patterned photoresist layer including a plurality of masking elements or features. During the developing process, a developing solution is applied to the photoresist layer. In one embodiment, the photoresist material that was exposed to the radiation is removed by the developing solution (developer). However, implementing a negative-tone resist is also possible. The developer or developing solution may be a positive tone developer or negative tone developer. One exemplary developer is aqueous tetramethylammonium hydroxide (TMAH).

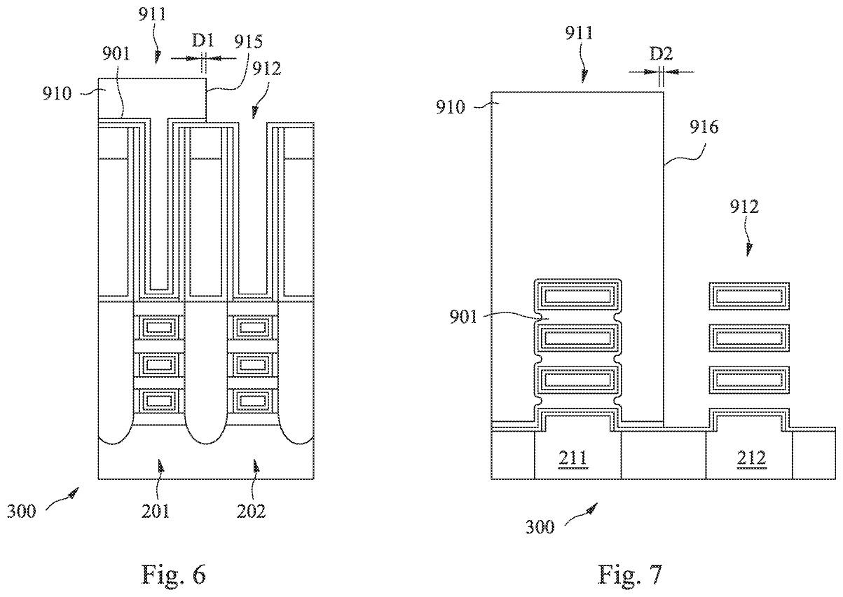

After developing the photoresist, the mask 910 is patterned and defines a covered region 911 of the underlying structure 300 that lies directly under the mask 910 and a non-covered region 912 of the underlying structure 300 that does not lie directly under the mask 910. In FIG. 6, the NFET region 201 is the covered region 911 and the PFET region 202 is the non-covered region 912. In FIG. 7, the NFET region 211 is the covered region 911 and the PFET region 212 is the non-covered region 912.

As shown in FIGS. 6-7, after patterning, the mask 910 has a side wall 915 and a side wall 916.

Cross-referencing FIGS. 1 and 6-7, method 100 further includes, at operation S105, etching the layer 901 from the non-covered region 912. Specifically, the layer 901 may be completely removed from the non-covered region 912.

In certain embodiments, the layer 901 is etched using a wet etch process performed with an etchant selected for use with the specific layer 901 and mask 910. In certain embodiments, the etch to remove layer 901 is isotropic. In certain embodiments, the etchant includes a first component, an oxidant, and water.

In certain embodiments, the first component is an organic acid having a molecular weight of from 14 to 10⁴ g/mol. In certain embodiments, the first component is an organic acid having a functional group including a Group III element, Group IV element, Group V element, Group VI element, and/or Group VII element. In certain embodiments, the first component is an organic acid, and the etchant has an organic acid concentration of from 0.001 to 100 wt. %.

In certain embodiments, the first component is an organic base having a molecular weight of from 20 to 10⁴ g/mol. In certain embodiments, the first component is an organic base having a functional group including a Group III element, Group IV element, Group V element, Group VI element, and/or Group VII element. In certain embodiments, the first component is an organic base, and the etchant has an organic base concentration of from 0.001 to 100 wt. %.

In certain embodiments, the oxidant is a peroxide, such as hydrogen peroxide. In certain embodiments, the oxidant is ozone. In certain embodiments, the oxidant is present in the etchant at a concentration of from 0.1 to 10⁷ ppm.

In certain embodiments, the etch process is performed at a temperature of from 10 to 70° C. For example, the etch process is performed at a temperature of at least 10° C., such as at least 20° C., at least 30° C., at least 40° C., at least 50° C., or at least 60° C. In certain embodiments, the etch process is performed at a temperature of no more than 70° C., such as no more than 60° C., no more than 50° C., no more than 40° C., no more than 30° C., or no more than 20° C. In certain embodiments, the etch process is performed at ambient or room temperature.

As stated above, the etchant is selected such that penetration of the mask 910 by the etchant is minimized or avoided. As shown in FIG. 6, the etchant may penetrate the mask 910 through side wall 915 by a lateral dimension D1, in the X-direction. Likewise, as shown in FIG. 7, the etchant may penetrate the mask 910 through side wall 916 by a lateral dimension D2, in the Y-direction. Dimension D1 and dimension D2 are each less than 5 nm, such as less than 4 nm, less than 3 nm, or less than 2 nm.

Cross-referencing FIGS. 1 and 8-9, method 100 continues at operation S106 with removing the mask 910 from the selected region 911.

Further, method 100 may continue at operation S107 with etching back the first material layer 901 in the covered region 911. Specifically, the portions of the first material layer 901 overlying the ILD structures 700, overlying the STI features 500, and overlying the uppermost nanosheet 402 are etched back to a vertical thickness of zero, i.e., the material layer 901 is removed from over the ILD structures 700, over the STI features 500, and over the uppermost nanosheet 402. After operation S107, the material layer 901 is only located under a respective nanosheet 402, and provides for merging the nanosheets 402. In certain embodiments, the etch process at operation S107 is anisotropic. In certain embodiments, the etch process at operation S107 is a dry etch or plasma etch.

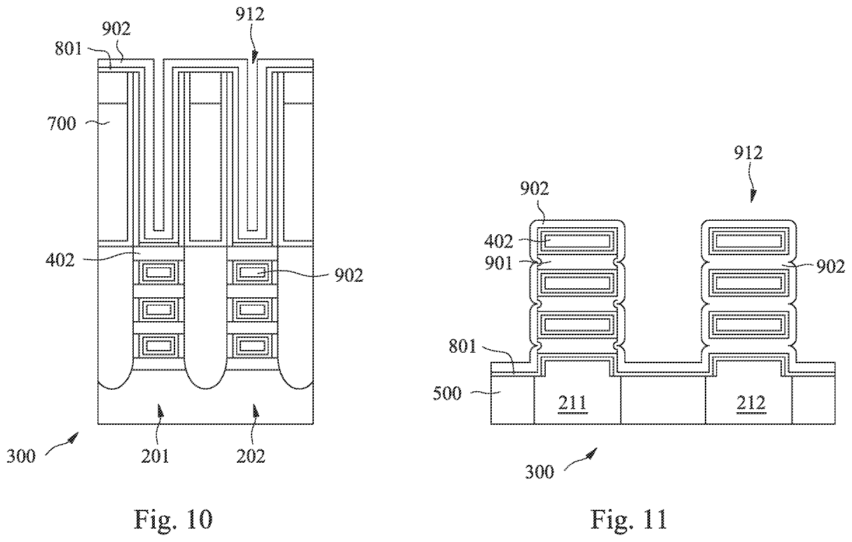

Cross-referencing FIGS. 1 and 10-11, method 100 continues at operation S108 with forming a second material layer 902 over the structure 300. Specifically, the material layer 902 may be conformally deposited over the gate dielectric layer 801 overlying the ILD structures 700, the uppermost nanosheet 402, and the STI features 500. In the non-covered regions 912, the material layer 902 surrounds the nanosheets 402. For example, the material layer 902 fills the space between nanosheets 402 and merges, as shown in FIGS. 10-11.

In certain embodiments, the material layer 902 is a transition metal. For example, in certain embodiments, the material layer 902 is a work function adjustment layer.

A work function adjustment layer 902 for a PFET region may include one or more layers of conductive material. Examples of the work function adjustment layer 902 for a PFET region include titanium, tungsten, vanadium, niobium, manganese, and/or molybdenum or similar metals. For example, the material layer 902 may be titanium nitride. In a certain embodiment, the thickness of the layer 902 is from 1 to 40 Å, such as from 20 to 35 Å, such as 30 Å.

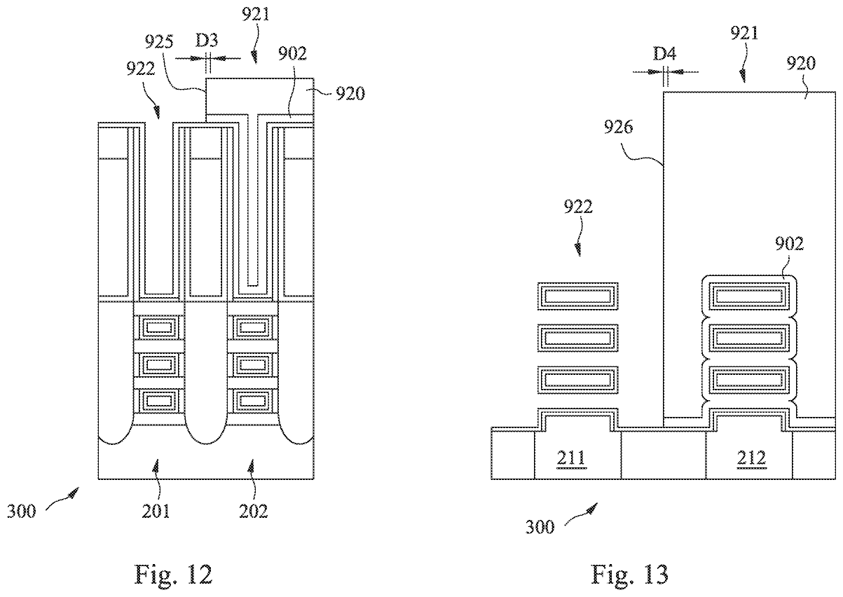

Cross-referencing FIGS. 1 and 12-13, method 100 further includes, at operation S109, covering a selected region of the structure with a mask 920. The mask 920 may include a coating, such as a bottom anti-reflective coating (BARC), reflective multilayers (ML), and a photoresist, and be patterned as described above in relation to FIGS. 6-7. After patterning, mask 920 defines a covered region 921 of the underlying structure 300 that lies directly under the mask 920 and a non-covered region 922 of the underlying structure 300 that does not lie directly under the mask 920. In FIG. 12, the PFET region 202 is the covered region 921 and the NFET region 201 is the non-covered region 922. In FIG. 7, the PFET region 212 is the covered region 921 and the NFET region 211 is the non-covered region 922.

As shown in FIGS. 12-13, after patterning, the mask 920 has a side wall 925 and a side wall 926.

Cross-referencing FIGS. 1 and 12-13, method 100 further includes, at operation S110, etching the layer 902 and layer 901 from the non-covered region 922. Specifically, the layer 902 and layer 901 may be completely removed from the non-covered regions 922.

In certain embodiments, layer 902 and layer 901 are etched using a wet etch process performed with an etchant selected for use with the specific layers 902 and 901 and mask 920. In certain embodiments, the etch to remove layer 902 and layer 901 is isotropic. In certain embodiments, the etchant includes a first component, an oxidant, and water.

In certain embodiments, the first component is an organic acid having a molecular weight of from 14 to 10⁴ g/mol. In certain embodiments, the first component is an organic acid having a functional group including a Group III element, Group IV element, Group V element, Group VI element, and/or Group VII element. In certain embodiments, the first component is an organic acid, and the etchant has an organic acid concentration of from 0.001 to 100 wt. %.

In certain embodiments, the first component is an organic base having a molecular weight of from 20 to 10⁴ g/mol. In certain embodiments, the first component is an organic base having a functional group including a Group III element, Group IV element, Group V element, Group VI element, and/or Group VII element. In certain embodiments, the first component is an organic base, and the etchant has an organic base concentration of from 0.001 to 100 wt. %.

In certain embodiments, the oxidant is a peroxide, such as hydrogen peroxide. In certain embodiments, the oxidant is ozone. In certain embodiments, the oxidant is present in the etchant at a concentration of from 0.1 to 10⁷ ppm.

In certain embodiments, the etch process is performed at a temperature of from 10 to 70° C. For example, the etch process is performed at a temperature of at least 10° C., such as at least 20° C., at least 30° C., at least 40° C., at least 50° C., or at least 60° C. In certain embodiments, the etch process is performed at a temperature of no more than 70° C., such as no more than 60° C., no more than 50° C., no more than 40° C., no more than 30° C., or no more than 20° C. In certain embodiments, the etch process is performed at ambient or room temperature.

As stated above, the etchant is selected such that penetration of the mask 920 by the etchant is minimized or avoided. As shown in FIG. 12, the etchant may penetrate the mask 920 through side wall 925 by a lateral dimension D3, in the X-direction. Likewise, as shown in FIG. 13, the etchant may penetrate the mask 920 through side wall 926 by a lateral dimension D4, in the Y-direction. Dimension D3 and dimension D4 are each less than 5 nm, such as less than 4 nm, less than 3 nm, or less than 2 nm.

Cross-referencing FIGS. 1 and 12-13, method 100 may continue at operation S111 with further processing, such as to complete formation of metal gates. For example, the mask 920 may be removed from the selected region 921 and additional metal layers may be formed during the formation of metal gates over the transistor regions 201, 202, 211 and 212. Further, a gate electrode material may be deposited over the transistor regions 201 and 211. An exemplary gate electrode material is a conductive material including one or more layers of a metal material, such as tungsten (W), cobalt (Co), ruthenium (Ru), or iridium (Ir), or other metals. In other embodiments, the conductive material includes a silicon alloy including one of titanium silicon alloy (TixSiy), cobalt silicon alloy (CoxSiy), Nickle silicon alloy (NixSiy), tungsten silicon alloy (WxSiy), molybdenum silicon alloy (MoxSiy), tantalum silicon alloy (TaxSiy), or other suitable conductive materials. In one embodiment, W is used. The conductive material is formed by CVD, PVD, ALD, electroplating or other suitable methods. Further processing may also the formation of interlayer dielectric and/or intermetal dielectric, formation of contacts and conductive interconnects and other back end of line processing.

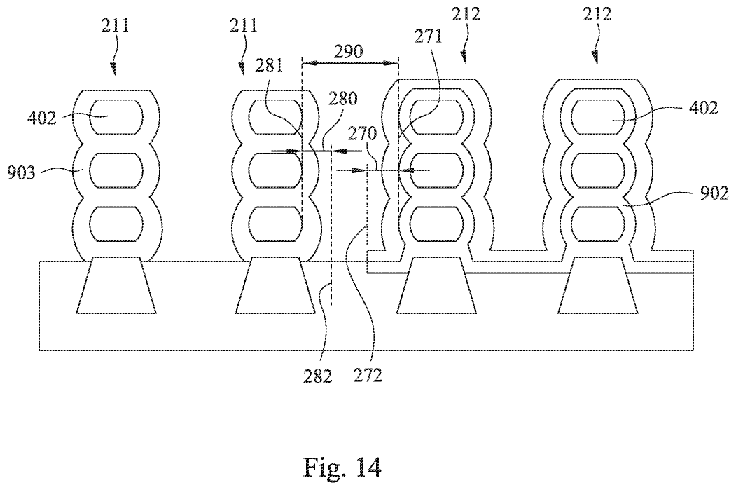

FIG. 14 is a cross-sectional view, similar to FIG. 13, and illustrating the formation of a third material layer 903 over the structure 300 in the NFET region 211 and PFET region 212. For example, the third layer 903 may be a work function adjustment layer for the NFET region 211, such as transition metal. For example, the third layer 903 may be TiAl.

Before the third material layer 903 is formed, the remaining portion of the second layer 902 has a vertical edge 271 spaced from a mask boundary 272 of mask 920, i.e., aligned with side wall 926. Due to the use of an etchant that penetrates only up to 2 nm into the mask 920 during the etch process, the distance 270 between the vertical edge 271 and the boundary 272 may be reduced, such as by 5 nm.

Based on the same etching processes, a vertical edge 281 of the nanosheets 402 in the region 211 may be distanced from a mask boundary 282 by a distance 280 that may also be reduced by 5 nm. Thus, the spacing between transistors may be reduced by 5 to 10 nm, such as by 10 nm. Inter-transistor distance 290 may be from 15 to 30 nm.

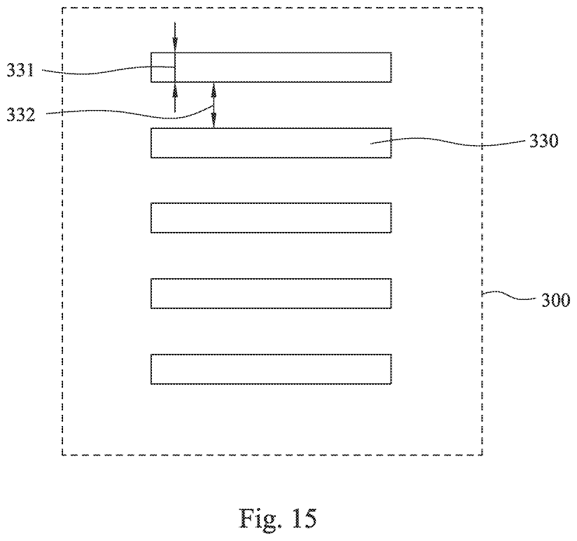

Referring now to FIG. 15, an overhead layout view of a semiconductor structure 300 is illustrated. Due to the reduced boundary loss during the etch processes of operations S105 and S110, the present method uses a reduced amount of boundary margin or tolerance. Oxide diffusion (OD, defining p-/n-active area for p-/n-field effect transistor) regions 330 are equally spaced on the structure 300. The oxide diffusion regions 330 are active regions in which one or more device features, e.g., a source/drain region, is formed.

As shown, each oxide diffusion region 330 has a same thickness 331. For example, thickness 331 may be from 11 to 30 nm, such as 13 nm. In such embodiments, the STI features may have a thickness of from 33 to 48 nm, such that an OD/STI ratio is from 0.23 to 0.91.

Further, adjacent oxide diffusion regions 330 are spaced apart from one another by a uniform distance 332. For example, uniform distance 332 may be from 36 to 46 nm, such as 36 nm.

With such a layout, the OD pattern density may be increased by 15 to 20%, such as by 17%, as compared to fabrication processes that do not reduce the mask boundary as by reducing mask penetration by etchants as described herein.

In certain embodiments, the wet penetration is reduced from 5 to 7 nm to less than 2 nm, a 71% improvement.

In certain embodiments, the critical dimension can be increased from 3 to 5 nm due to the decrease in necessary boundary margin.

In certain embodiments, the transistor density improvement is improved by the wet penetration improvement of 5 nm over the OD-OD spacing of 26 nm, for an improvement of 19.3%.

In certain embodiments, the OD-OD spacing may be reduced from 26 nm to 16 nm, a decrease of from 15 to 20%.

In certain embodiments, the pH of the etchant is tuned to reduce penetration into the mask and reduce metal boundary shift.

In certain embodiments, metal boundary loss reduction provides for higher transistor density.

In an embodiment, method includes forming a first structure and a second structure over a substrate; forming a material layer over each structure; covering the first structure with a mask, wherein the second structure is uncovered; and performing an etch process to remove the material layer from the second structure, wherein the etch process is performed with an etchant comprising a first component and an oxidant, and wherein the first component is selected from an organic acid having a molecular weight of from 14 to 10⁴ g/mol and an organic base having a molecular weight of from 20 to 10⁴ g/mol.

In certain embodiments of the method, each structure includes at least one nanosheet, and forming the material layer over each structure includes depositing the material layer around each nanosheet.

In certain embodiments of the method, the material layer includes a transition metal, and the material layer is formed with a thickness of from 0.5 to 20 nm.

In certain embodiments of the method, the first component is present in the etchant at a concentration of at least 0.001 wt. %.

In certain embodiments of the method, the oxidant is present in the etchant at a concentration of from 0.1 to 10⁷ ppm.

In certain embodiments of the method, the etch process is performed at a temperature of from 10 to 70° C.

In certain embodiments of the method, the first component is an organic acid having a molecular weight of from 14 to 10⁴ g/mol and having a functional group including a Group III element, Group IV element, Group V element, Group VI element, and/or Group VII element.

In certain embodiments of the method, the first component is an organic base having a molecular weight of from 20 to 10⁴ g/mol and having a functional group including a Group III element, Group IV element, Group V element, Group VI element, and/or Group VII element.

In certain embodiments of the method, after covering the first structure with the mask, the mask has a side wall, and while performing the etch process the etchant penetrates the side wall of the mask to a dimension of less than 2 nm.

In another embodiment, a method includes forming a first gate-all-around (GAA) FET structure in a first transistor region including at least one nanosheet; forming a second gate-all-around (GAA) FET structure in a second transistor region adjacent to the first transistor region including at least one nanosheet, wherein the second GAA FET structure is located at a distance of less than 20 nm from the first GAA FET structure; forming a work function adjustment layer over the first GAA FET structure and the second GAA FET structure; forming a mask over the first GAA FET structure, wherein the second GAA FET structure is uncovered; and performing an etch process with an etchant to remove the work function adjustment layer from the second GAA FET structure, wherein the etchant penetrates the mask to a dimension of less than 5 nm.

In certain embodiments of the method, the etchant penetrates the mask to a dimension of less than 2 nm.

In certain embodiments of the method, the work function adjustment layer is titanium, tungsten, vanadium, niobium, manganese, molybdenum, or aluminum.

In certain embodiments of the method, the work function adjustment layer has a thickness of from 10 to 40 Å.

In certain embodiments of the method, the etchant includes a first component, an oxidant, and water, and the first component is an organic acid having a molecular weight of from 14 to 10⁴ g/mol and having a functional group including a Group III element, Group IV element, Group V element, Group VI element, and/or Group VII element.

In certain embodiments of the method, the etchant includes a first component, an oxidant, and water, and the first component is an organic base having a molecular weight of from 20 to 10⁴ g/mol and having a functional group including a Group III element, Group IV element, Group V element, Group VI element, and/or Group VII element.

In certain embodiments of the method, the etchant includes a first component and an oxidant, the first component is selected from an organic acid and an organic base, and the first component is present in the etchant at a concentration of at least 0.001 wt. %.

In certain embodiments of the method, the etchant includes a first component and an oxidant, the first component is selected from an organic acid and an organic base, and the oxidant is present in the etchant at a concentration of from 0.1 to 10⁷ ppm.

In certain embodiments of the method, the etchant includes a first component and an oxidant, the first component is selected from an organic acid and an organic base, and the oxidant is hydrogen peroxide.

In another embodiment, a semiconductor structure includes a p-channel metal-oxide semiconductor (PMOS) region; an n-channel metal-oxide semiconductor (NMOS) region; and oxide diffusion layer (OD) structures located in the PMOS region and the NMOS region, wherein the OD structures are uniformly spaced from one another by a distance of less than 20 nm.

In certain embodiments, the OD structures are uniformly spaced from one another by a distance of 16 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first structure and a second structure over a substrate;
forming a material layer over each structure;
covering the first structure with a mask, wherein the second structure is uncovered; and
performing an etch process to remove the material layer from the second structure, wherein the etch process is performed with an etchant comprising a first component and an oxidant, and wherein the first component is selected from an organic acid having a molecular weight of from 14 to 10⁴ g/mol and an organic base having a molecular weight of from 20 to 10⁴ g/mol.

2. The method of claim 1, wherein each structure includes at least one nanosheet, and wherein forming the material layer over each structure comprises depositing the material layer around each nanosheet.

3. The method of claim 1, wherein the material layer comprises a transition metal, and wherein the material layer is formed with a thickness of from 0.5 to 20 nm.

4. The method of claim 1, wherein the first component is present in the etchant at a concentration of at least 0.001 wt. %.

5. The method of claim 1, wherein the oxidant is present in the etchant at a concentration of from 0.1 to 10⁷ ppm.

6. The method of claim 1, wherein the etch process is performed at a temperature of from 10 to 70° C.

7. The method of claim 1, wherein the first component is an organic acid having a molecular weight of from 14 to 10⁴ g/mol and having a functional group including a Group III element, Group IV element, Group V element, Group VI element, and/or Group VII element.

8. The method of claim 1, wherein the first component is an organic base having a molecular weight of from 20 to 10⁴ g/mol and having a functional group including a Group III element, Group IV element, Group V element, Group VI element, and/or Group VII element.

9. The method of claim 1, wherein after covering the first structure with the mask, the mask has a side wall, and wherein while performing the etch process the etchant penetrates the side wall of the mask to a dimension of less than 2 nm.

10. A method comprising:
forming a first gate-all-around (GAA) FET structure in a first transistor region including at least one nanosheet;
forming a second gate-all-around (GAA) FET structure in a second transistor region adjacent to the first transistor region including at least one nanosheet, wherein the second GAA FET structure is located at a distance of less than 20 nm from the first GAA FET structure;
forming a work function adjustment layer over the first GAA FET structure and the second GAA FET structure;
forming a mask over the first GAA FET structure, wherein the second GAA FET structure is uncovered; and
performing an etch process with an etchant to remove the work function adjustment layer from the second GAA FET structure, wherein the etchant penetrates the mask to a dimension of less than 5 nm.

11. The method of claim 10, wherein the etchant penetrates the mask to a dimension of less than 2 nm.

12. The method of claim 10, wherein the work function adjustment layer is titanium, tungsten, vanadium, niobium, manganese, molybdenum, or aluminum.

13. The method of claim 10, wherein the work function adjustment layer has a thickness of from 10 to 40 Å.

14. The method of claim 10, wherein the etchant comprises a first component, an oxidant, and water, and wherein the first component is an organic acid having a molecular weight of from 14 to 10⁴ g/mol and having a functional group including a Group III element, Group IV element, Group V element, Group VI element, and/or Group VII element.

15. The method of claim 10, wherein the etchant comprises a first component, an oxidant, and water, and wherein the first component is an organic base having a molecular weight of from 20 to 10⁴ g/mol and having a functional group including a Group III element, Group IV element, Group V element, Group VI element, and/or Group VII element.

16. The method of claim 10, wherein the etchant comprises a first component and an oxidant, wherein the first component is selected from an organic acid and an organic base, and wherein the first component is present in the etchant at a concentration of at least 0.001 wt. %.

17. The method of claim 10, wherein the etchant comprises a first component and an oxidant, wherein the first component is selected from an organic acid and an organic base, and wherein the oxidant is present in the etchant at a concentration of from 0.1 to 10⁷ ppm.

18. The method of claim 10, wherein the etchant comprises a first component and an oxidant, wherein the first component is selected from an organic acid and an organic base, and wherein the oxidant is hydrogen peroxide.

19. A semiconductor structure comprising:
a p-channel metal-oxide semiconductor (PMOS) region;
an n-channel metal-oxide semiconductor (NMOS) region; and
oxide diffusion layer (OD) structures located in the PMOS region and the NMOS region, wherein the OD structures are uniformly spaced from one another by a distance of less than 20 nm.

20. The semiconductor structure of claim 19, wherein the OD structures are uniformly spaced from one another by a distance of 16 nm.
